(19) United States
(12) Patent Application Publication
(10) Pub. No.: US 2017/0207287 A1
(43) Pub. Date: Jul. 20, 2017

(54) DISPLAY DEVICE

(71) Applicant: Japan Display Inc., Tokyo (JP)

(72) Inventors: Ikuo MATSUNAGA, Tokyo (JP); Kenta KAJIYAMA, Tokyo (JP)

(21) Appl. No.: 15/334,335

(22) Filed: Oct. 26, 2016

(30) Foreign Application Priority Data
Jan. 15, 2016 (JP) 2016-005960

(51) Int. Cl. H01L 27/32

(52) U.S. Cl. CPC H01L 27/3265; H01L 27/3248; H01L 27/3258; H01L 2227/323; H01L 2251/5392

(57) ABSTRACT

A display device in an embodiment according to the present invention includes a conductive layer over an interlayer insulating layer, a pixel electrode over the conductive layer, and an insulating layer provided between the conductive layer and the pixel electrode. The pixel electrode is electrically connected to a transistor via a contact hole through the insulating layer and the interlayer insulating layer, the conductive layer has an opening having the contact hole inside and spreading to an outer region outside of the pixel electrode, the opening has an open end, and one side of the opening bends in the outer region outside of the pixel electrode.

### CROSS REFERENCE TO RELATED APPLICATIONS

This application is based upon and claims the benefit of priority from the prior Japanese Patent Application No. 2016-005960 filed on Jan. 15, 2016, the entire contents of which are incorporated herein by reference.

### FIELD

The present invention relates to display devices. An embodiment of the invention disclosed herein relates to a configuration of a pixel unit in a display device.

### BACKGROUND

A light-emitting element is currently under development that has a structure in which a layer containing an organic electroluminescence material is sandwiched between a pair of electrodes. The light-emitting element emits light in response to the application of a predetermined voltage between the pair of electrodes. The emission intensity of the light-emitting element is controlled by the amount of current.

A display device whose pixels are constituted by light-emitting elements is called an organic electroluminescence display device or an organic EL display device. As with a liquid crystal display device, the organic EL display device is provided with a circuit that drives the pixels with thin-film transistors. For example, a display device is disclosed that includes elements such as light-emitting elements arranged in pixels, transistors that drive the light-emitting elements, retentive capacitive elements that retain gate voltages of the transistors, and auxiliary capacitive elements that adjust the amounts of current that flow to the light-emitting elements (see, for example, Japanese Unexamined Patent Application Publication No. 2014-085384).

Each of the elements that is used in driving the pixels are fabricated by processing conductor films of metal or the like and semiconductor films into fine patterns by photolithographic techniques. Furthermore, the circuit of the display device is integrated by providing an insulating film between elements or between layers of wiring. As with semiconductor integrated circuits, techniques for manufacturing display devices have moved to finer design rules, thereby moving pixels to finer resolution.

### SUMMARY

A display device in an embodiment according to the present invention includes a conductive layer over an interlayer insulating layer, a pixel electrode over the conductive layer, and an insulating layer provided between the conductive layer and the pixel electrode. The pixel electrode is electrically connected to a transistor via a contact hole through the insulating layer and the interlayer insulating layer, the conductive layer has an opening having the contact hole inside and spreading to an outer region outside of the pixel electrode, the opening has an open end, and one side of the opening bends in the outer region outside of the pixel electrode.

A display device in an embodiment according to the present invention includes a conductive layer over an interlayer insulating layer, a plurality of pixel electrodes arranged over the conductive layer, and an insulating layer provided between the conductive layer and the plurality of pixel electrodes. Each of the pixel electrodes is electrically connected to a transistor via a contact hole through the insulating layer and the interlayer insulating layer, each of the pixel electrodes, the conductive layer has a plurality of openings having the contact holes inside and spreading to outer regions outside of the pixel electrodes, respectively, each of the openings has an open end, and one side of the each of the opening bends in the outer regions outside of the pixel electrodes.

### BRIEF DESCRIPTION OF THE DRAWINGS

FIG. 1 is a perspective view showing a display device according to an embodiment of the present invention;

FIG. 2 is a diagram showing a configuration of the display device according to the embodiment of the present invention;

FIG. 3 is a diagram explaining a pixel circuit of the display device according to the embodiment of the present invention;

FIG. 4 is a plan view showing a layout of a pixel of the display device according to the embodiment of the present invention;

FIG. 5 is a cross-sectional view showing a configuration of the pixel of the display device according to the embodiment of the present invention;

FIG. 6 is a plan view showing a configuration of a pixel unit of the display device according to the embodiment of the present invention;

FIG. 7 is a plan view showing a layout of pixels of the display device according to the embodiment of the present invention;

FIG. 8 is a cross-sectional view showing a configuration of the pixels of the display device according to the embodiment of the present invention;

FIG. 9 is a plan view showing a configuration of the pixel unit of the display device according to the embodiment of the present invention;

FIG. 10 is a plan view showing a configuration of the pixel unit of the display device according to the embodiment of the present invention;

FIG. 11 is a plan view showing a configuration of the pixel unit of the display device according to the embodiment of the present invention; and

FIG. 12 is a plan view showing a configuration of the pixel unit of the display device.

### DESCRIPTION OF EMBODIMENTS

An embodiment of the present invention is described below with reference to the drawings and the like. Note, however, that the present invention may be carried out in many different aspects and should not be narrowly interpreted within the limits of the contents of description of the embodiment illustrated below. For a clearer description, the drawings may schematically show the width, thickness, shape, and the like of each component in comparison with actual aspects; however, they are mere examples and, as such, are not intended to limit the interpretation of the present invention. Further, in the present specification and each of the drawings, elements that are identical to those previously described with reference to a preceding drawing are given the same reference numerals (or reference numerals each with a letter such as “a” or “b” added to the end of a number), and a detailed description of such elements may be omitted as appropriate. Furthermore, a word “first” or “second” added to the beginning of an element is a convenient mark that is used for identifying the element, and means nothing more than that unless otherwise noted.

In the present specification, unless otherwise noted, cases where a member or region is located “over (or under)” another member or region encompass not only cases where a member or region is located immediately above (or immediately below) another member or region but also cases where a member or region is located above (or below) another member or region, i.e. cases where another constituent element is inserted above (or below) another member or region. It should be noted that, unless otherwise noted, the following description assumes that, in a cross-sectional view, the side of a first substrate on which a second substrate is arranged is referred to as “over” or “above” and the opposite side is referred to as “under” or “below”.

In the present specification, a display device includes a first substrate. The first substrate has at least one planar principal surface over which a plurality of thin films are provided to form elements. The following description bases a cross-sectional view on the principal surface of the first substrate and refers to the upper side of the principal surface as “over”, “higher level”, or “above”.

An increase in pixel density along with finer pixel resolution leads to a reduction in space between adjacent pixels. However, in a process for manufacturing a display device, for example, a defect in a step of patterning a pixel electrode causes adjacent pixels to be short-circuited to cause a display defect. Of course, in the manufacturing process, strict controls are placed so that there is no contamination with particles that cause a patterning defect. Nevertheless, there is undesirably a possibility of a defect that causes pixel electrodes to be short-circuited.

The following embodiment discloses a display device that can be free of such a display defect.

### 1. Overview of Display Device

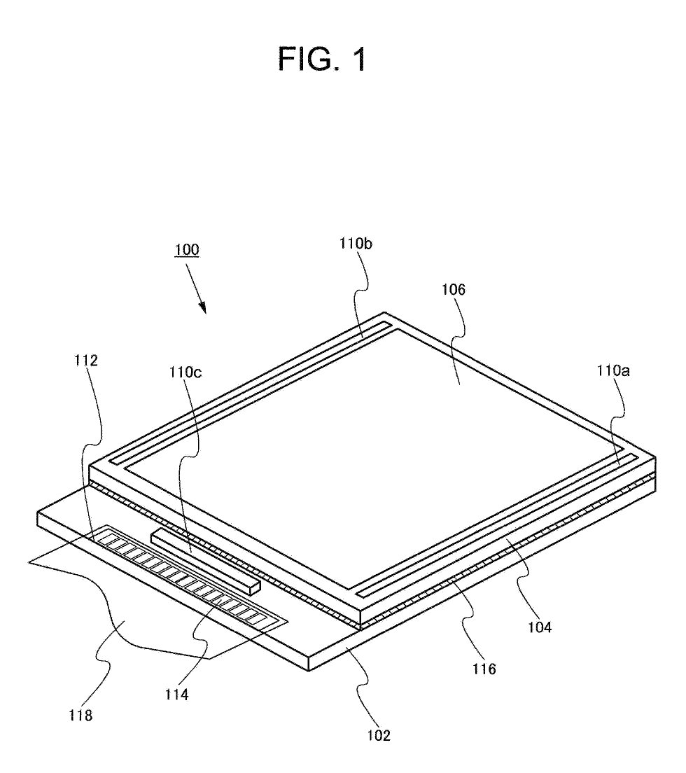

FIG. 1 is a perspective view of a display device 100 according to an embodiment of the present invention. The display device 100 includes a first substrate 102 provided with a pixel unit 106, drive circuits 110 (namely a first drive circuit 110a, a second drive circuit 110b, and a third drive circuit 110c), and a terminal unit 112. The display device 100 includes a second substrate 104 placed opposite the first substrate 102. The first substrate 102 and the second substrate 104 are fixed by a seal member 116. The second substrate 104 is arranged to cover a pixel unit 106. As with the first substrate 102, the second substrate 104 is for example a plate member. Alternatively, without being limited to this, the second substrate 104 may be an organic resin film, a laminate of an organic resin film and an inorganic insulating film, or a sheet-like organic resin substrate. The terminal unit 112 is constituted by a plurality of terminals 114 and arranged at a side edge portion of the first substrate 102. The terminal unit 112 is connected to a wiring substrate 118 via an anisotropic conductive film. The wiring substrate 118 connects the display device 100 to another functional circuit or an external device, and is used to send and receive signals.

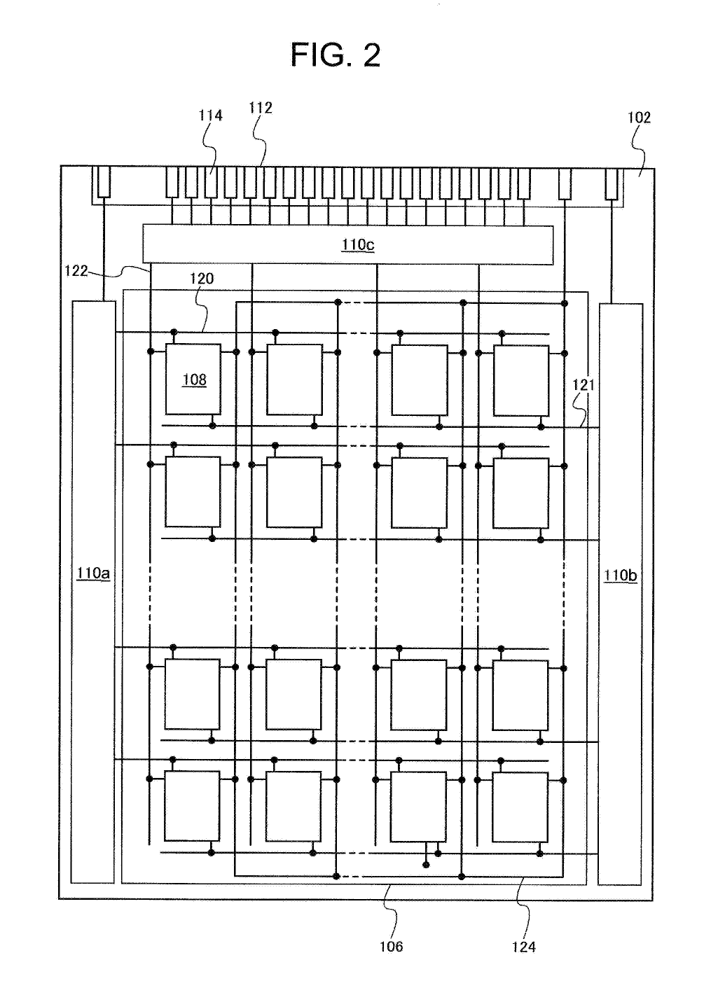

FIG. 2 shows a circuit configuration of the display device 100. In the display device 100, signals that drive the display device 100 are inputted from the terminal unit 112 to the first drive circuit 110a, the second drive circuit 110b, and the third drive circuit 110c. The first drive circuit 110a outputs signals to first scanning signal lines 120. The second drive circuit 110b outputs signals to second scanning signal lines 121. The third drive circuit 110c outputs signals to video signal lines 122. These signals are sent to the pixel unit 106 through the first scanning signal lines 120, the second scanning signal lines 121, and the video signal lines 122.

The pixel unit 106 includes pixels 108 arranged in rows and columns. Any number of pixels 108 may be arranged. For example, the pixels 108 are arranged in m rows (along the X axis) and n columns (along the Y axis). Although FIG. 2 shows an example in which the pixels 108 are squarely arranged, the present invention is not limited to this example. The pixels 108 may be arranged in another matrix such as a delta matrix or a Pen Tile matrix. In the pixel unit 106, the first scanning signal lines 120 and the second scanning signal lines 121 extend in a row-wise direction, and the video signal lines 122 extend a column-wise direction. Further, as shown in FIG. 2, the display device 100 has power supply lines 124 provided in the pixel unit 106.

### 2. Configuration of Pixel

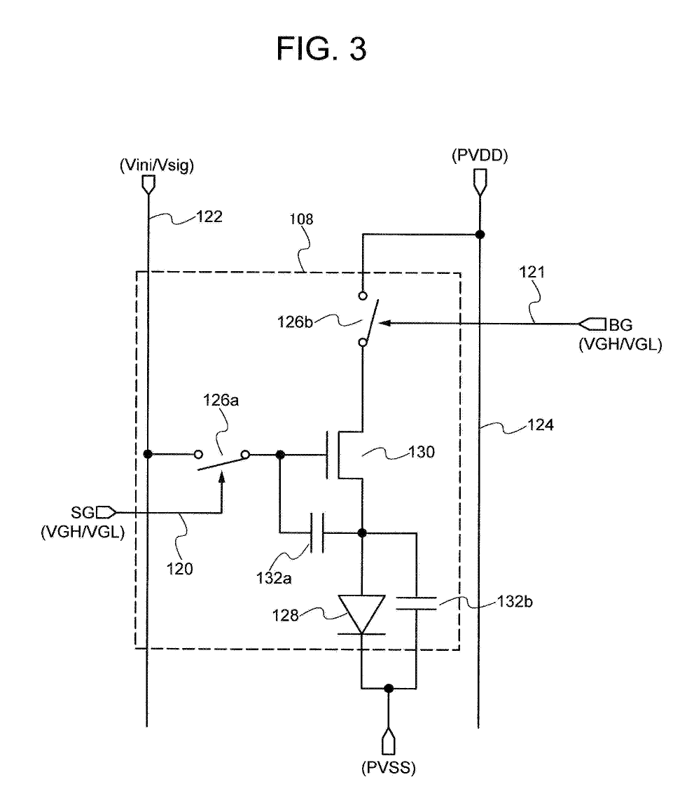

FIG. 3 shows an example of a circuit configuration of each of the pixels 108. The pixel 108 includes switching elements 126 (namely a first switching element 126a and a second switching element 126b), a light-emitting element 128, a transistor 130 (hereinafter referred to as “drive transistor”) that drives the light-emitting element 128, and capacitive elements 132 (namely a first capacitive element 132a and a second capacitive element 132b). With these elements, the pixel 108 forms a circuit (hereinafter referred to as “pixel circuit”).

The drive transistor 130 includes a gate, a source, and a drain. The gate serves as a control terminal, and the source and the drain serve as input and output terminals. The pixel circuit shown in FIG. 3 shows an example in which the drive transistor 130 has its gate connected to a video signal line 122 via the first switching element 126a, its drain connected to a power supply line 124 via the second switching element 126b, and its source connected to the light-emitting element 128. It should be noted that, in the pixel circuit shown in FIG. 3, the drive transistor 130 is of an N-channel transistor.

The operation of turning on and off the first switching element 126a is controlled by a control signal SG (having amplitude VGH/VGL) from a first scanning signal line 120. When the first switching element 126a is on, an electric potential based on a video signal Vsig from the video signal line 122 is supplied to the gate of the drive transistor 130. Further, the operation of turning on and off the second switching element 126b is controlled by a control signal BG (having amplitude VGH/VGL) from a second scanning signal line 121. When the second switching element 126b is turned on, an electric potential of the power supply line 124 is applied to the drain of the drive transistor 130. It should be noted that the control signal VGH is a high-potential signal that turns on the first switching element 126a and the second switching element 126b and the control signal VGL is a low-potential signal that turns off the first switching element 126a.

The first capacitive element 132a is provided between the source and gate of the drive transistor 130. The first capacitive element 132a retains a gate voltage of the drive transistor 130. Further, the second capacitive element 132b is connected to the source of the drive transistor 130. The second capacitive element 132b is charged by a drain current of the drive transistor 130, and functions to adjust the amount of emission current of the light-emitting element 128. In such a circuit configuration of the pixel 108, when a voltage based on a video signal is supplied to the gate of the drive transistor 130 and the second switching element 126b is turned on, an electric current flow from the power supply line 124 to the light-emitting element 128 via the drive transistor 130. When a voltage that is equal to or higher than an emission threshold voltage is applied, the light-emitting element 128 emits light in accordance with the amount of current that flows.

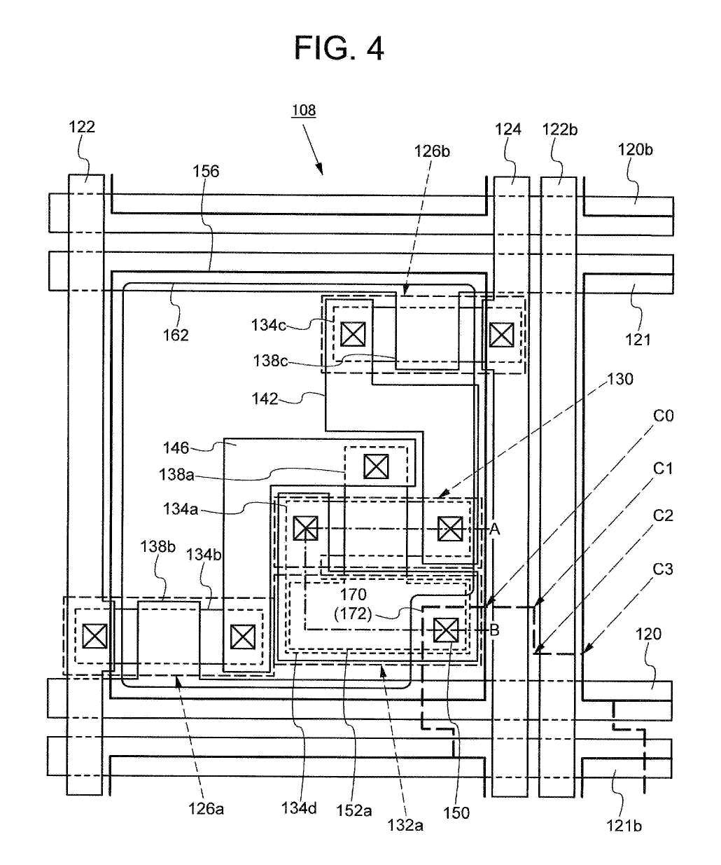

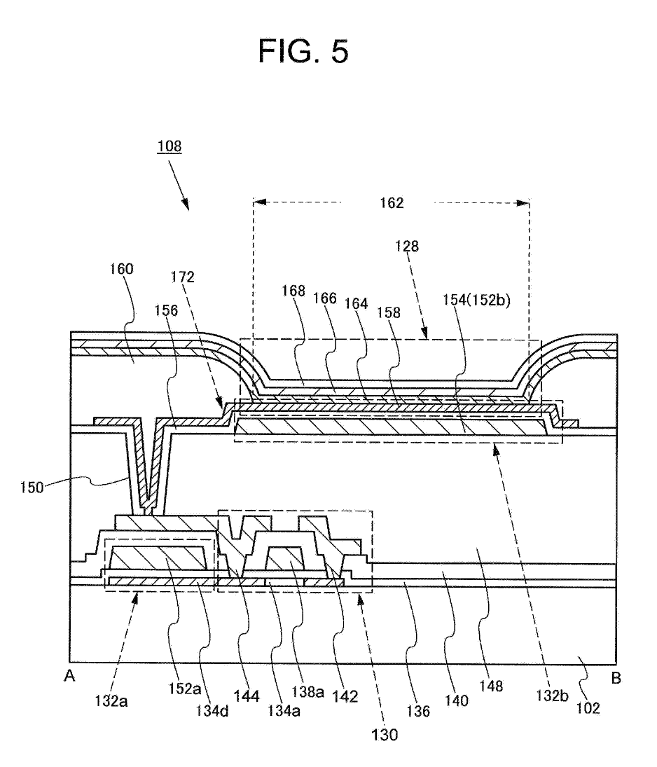

FIG. 4 is a plan view showing an arrangement of the drive transistor 130, first switching element 126a, second switching element 126b, first capacitive element 132a, and second capacitive element 132b of the pixel 108. Further, FIG. 5 shows a cross-sectional structure of the pixel 108 as taken along line A-B in FIG. 4. The configuration of the pixel 108 is described below with reference to FIG. 4 and FIG. 5.

The drive transistor 130 has a structure in which a semiconductor layer 134a, a gate insulating layer 136, and a gate electrode 138a are stacked. The gate electrode 138a is formed by a first conductive layer provided over the gate insulating layer 136. The first conductive layer is formed by a metal film of aluminum, titanium, molybdenum, tungsten, or the like. For example, the first conductive layer has a structure in which titanium and aluminum are stacked. A first insulating layer 140 is provided on a higher level than the gate electrode 138a. The first insulating layer 140 is made of an inorganic insulating material. For example, the first insulating layer 140 has a structure in which a silicon oxide film and a single or plural silicon oxide films are stacked. A drain wire 142 and a source wire 144 are provided over the first insulating layer 140. The drain wire 142 and the source wire 144 are formed by a second conductive layer. The second conductive layer is formed by a metal film of titanium, molybdenum, aluminum, or the like. For example, the second conductive layer has a structure in which an aluminum film is sandwiched between upper and lower titanium films.

The drive transistor 130 has its drain electrically connected to the second switching element 126b through the drain wire 142. The source wire 144 is electrically connected to the source of the drive transistor 130. A second insulating layer 148 is provided over the drain wire 142 and the source wire 144. The second insulating layer 148 is formed by an inorganic insulating film or an organic insulating film. The organic insulating film is made of an organic insulating material such as acrylic or polyimide. A pixel electrode 158 is provided on a higher level than the second insulating layer 148. The second insulating layer 148 is used as a planarizing film to planarize an upper surface on which the pixel electrode 158 is provided. The pixel electrode 158 is electrically connected to the source wire 144 via a contact hole 150 provided at least in the second insulating layer 148. That is, the pixel electrode 158 is electrically connected to the drive transistor 130 through the source wire 144.

The first switching element 126a is achieved by a transistor having the same structure as the drive transistor 130. The first switching element 126a includes a semiconductor layer 134b, a gate electrode 138c, and the gate insulating layer 136. Similarly, the second switching element 126b includes a semiconductor layer 134c, a gate electrode 138c, and the gate insulating layer 136. The gate electrode 138b is electrically connected to the first scanning signal line 120, and either of the input and output terminals is electrically connected to the video signal line 122. In the second switching element 126b, the gate electrode 138c is electrically connected to the second scanning signal line 121, and either of the input and output terminals is electrically connected to the power supply line 124.

The first capacitive element 132a uses the gate insulating layer 136 as a dielectric layer. The first capacitive element 132a uses, as its first electrode (first capacitive electrode 152a), the first conductor layer provided over the gate insulating layer 136. The first capacitive element 132a uses, at its second electrode, a semiconductor layer 134d provided on a lower level than the gate insulating layer 136. The semiconductor layer 134d, which serves as the second electrode of the first capacitive element 132a, is a region extending from the semiconductor layer 134a of the drive transistor 130. It is preferable that the semiconductor layer 134d contain impurities of the same conductivity type as a source region and drain region of the drive transistor 130 (impurity regions provided in the semiconductor layer 134a) and be low in resistance. This allows the first capacitive element 132a to be electrically connected to the source of the drive transistor 130.

The second capacitive element 132b uses, as one electrode (second capacitive electrode 152b) thereof, a third conductive layer 154 provided on the upper surface of the second insulating layer 148. A third insulating layer 156 is provided on a higher level than the third conductive layer 154. The third insulating layer 156 serves as a dielectric film of the second capacitive element 132b. The pixel electrode 158 is provided on an upper surface of the third insulating layer 156. The second capacitive element 132b is formed in a region where the third conductive layer 154, the third insulating layer 156, and the pixel electrode 158 overlap. The electrode of the second capacitive element 132b is electrically connected to the source of the drive transistor 130 by being used also as the pixel electrode 158. It should be noted that the third conductive layer 154 is formed by a metal film of aluminum, titanium, molybdenum, tungsten, or the like. By thus using the pixel electrode 158 also as an electrode of a capacitive element, a light-emitting element serving as a display element and the capacitive element are stacked, so that the pixel can have a higher aperture ratio.

The gate electrode 138a of the drive transistor 130 is electrically connected to the first switching element 126a through a gate wire 146. The gate wire 146 is a wire that is provided in a different layer from the gate electrode 138a. The gate wire 146 is formed, for example, by the same second conductive layer as the drain wire 142 and the source wire 144.

The light-emitting element 128 includes the pixel electrode 158, an organic layer 164, and a counter electrode 166 as its constituent elements. The light-emitting element 128 has a light-emitting region where the pixel electrode 158, the organic layer 164, and the counter electrode 166 overlap. An outer edge portion of the pixel electrode 158 and a region of the pixel electrode 158 where the contact hole 150 is provided are covered with a fourth insulating layer 160. The fourth insulating layer 160 is arranged on a higher level than the pixel electrode 158 and has an opening 162 through which an inner region of the pixel electrode 158 is exposed. The organic layer 164 and the counter electrode 166 are provided in an area extending from an upper surface of the pixel electrode 158 to an upper surface of the fourth insulating layer 160.

The organic layer 164 is constituted by one or more layers and contains an organic electroluminescence material. The counter electrode 166 is provided on a higher level than the organic layer 164. A fifth insulating layer 168 is provided as a passivation layer on a higher level than the counter electrode 166. The fifth insulating layer 168 has a structure in which a single silicon nitride film, a laminate of a silicon nitride film and a silicon oxide film, a silicon nitride film, and an organic insulating film are stacked.

The light-emitting element 128 emits light when a voltage that is equal to or higher than the emission threshold voltage is applied between the pixel electrode 158 and the counter electrode 166. In the present embodiment, the display device 100 is of a so-called top-emission type, in which light is emitted from the side of the counter electrode 166. At this point in time, the pixel electrode 158, which serves as a reflecting electrode, adopts a configuration in which light emitted by the organic layer 164 is reflected by a laminated structure of a transparent conductive film and a metal film. For example, the pixel electrode 158 includes at least two transparent conductive films and a metal film (a preferred example of which is a high-reflectance material such as silver (Ag) or aluminum (Al)) sandwiched between the two transparent conductive films. The counter electrode 166 is formed by a transparent conductive film of indium oxide, tin oxide, or the like and transmits the light emitted by the organic layer 164.

The third conductive layer 154, which serves as the electrode (second capacitive electrode 152b) of the second capacitive element 132b, spreads substantially all over the pixel unit 106. In each pixel, the third conductive layer 154 has an opening 170 in a position where the contact hole 150 is provided. FIG. 4 uses a dotted line to indicate an open end of the opening 170 of the third conductive layer 154. The opening 170 of the third conductive layer 154 is a through-hole through which the second insulating layer 148, which is on a lower level than the third conductive layer 154, is exposed. The third insulating layer 156 covers an upper surface of the third conductive layer 154, the upper surface of the second insulating layer 148, and a step formed by the opening 170 of the third conductive layer 154. The third insulating layer 156 is formed by an inorganic insulating film such as a silicon nitride film or a silicon oxide film. Therefore, a surface of the third insulating layer 156 reflects the shape of the step at the open end formed by the opening 170 of the third conductive layer 154. Therefore, the third insulating layer 156 has a stepped portion 172 formed by providing the opening 170 in the third conductive layer 154.

The pixel electrode 158 is provided in an area extending from the upper surface of the third conductive layer 154 to a region of the third conductive layer 154 where the opening 170 is provided (region including the contact hole 150 formed in the second insulating layer 148). Therefore, the pixel electrode 158 is provided with a part covering the stepped portion 172. However, as shown in FIG. 5, the region in the pixel electrode 158 that overlaps the stepped portion 172 is covered with the fourth insulating layer 160 and therefore does not serve as a light-emitting region.

The third conductive layer 154 is electrically insulated from the pixel electrode 158 by being covered with the third insulating layer 156 and having the opening 170 surrounding the contact hole 150 formed in the second insulating layer 148. The contact hole 150 is arranged at an end of the pixel. Therefore, the opening 170 of the third conductive layer 154 is arranged to overlap an end of the pixel electrode 158 and has a part spreading to an outer region outside of the pixel electrode 158.

An open end of the third insulating layer 156 in the opening 170 includes a bending portion in the outer region outside of the pixel electrode 158. For example, as shown in FIG. 4, the open end of the opening 170 includes at least two bend portions C1 and C2. That is, the open end bends at the bend portions C1 and C2 in a path extending from a point C0 to a point C3 in the open end of the opening 170. Since the open end of the opening 170 bends between the points C0 and C3 in this manner, the length of one side of the open end is longer than the direct distance between the points C0 and C3.

At least one side of the open end of the opening 170 in the third conductive layer 154 includes a first side extending in a direction normal to one side of the pixel electrode 158 and a second side extending in such a direction as to cross the first side.

By thus providing an opening in a conductive layer arranged on a lower level than the pixel electrode 158 with an insulating layer interposed therebetween and bending an open end of the opening in the conductive layer, the length of the open end (i.e. the length of the contours of the open end) can be made substantially longer.

In this case, since the pixel electrode 158 overlaps the stepped portion 172 of the third insulating layer 156, the stepped portion 172 exerts a problematic influence on the manufacturing process. That is, the presence of the stepped portion 172 on the surface of the third insulating layer 156 due to the opening 170 of the third conductive layer 154 raises concern that when the pixel electrode 158 is formed by patterning a fourth conductive layer formed on the upper surface of the third insulating layer 156, a remnant (residue) of the fourth conductive layer is produced along the stepped portion 172. The production of such a residue along the stepped portion 172 of the third insulating layer 156 can cause a defect, as the residue has conductivity. An example of such a defect is a defect that brings the pixel electrode 158 into conduction with an adjacent pixel electrode.

The present embodiment is devised to prevent a defect from being caused in such a case even when the third insulating layer 156, which serves as a foundation surface for the pixel electrode 158, includes the stepped portion 172. That is, in the opening 170 of the third conductive layer 154, one side that extends along the open end is made to be a longer side. Even when a residue produced as the result of patterning the pixel electrode 158 remains along the stepped portion 172 extending along the open end of the opening 170, a conductive path extending along the stepped portion 172 inevitably becomes longer. This causes a conductive path formed by a residual substance to become longer and higher in resistance. As a result, even when the residual substance is produced between the pixel electrodes, a defect that causes the pixel electrodes to be short-circuited can be prevented.

### 3. Configuration of Pixel Unit

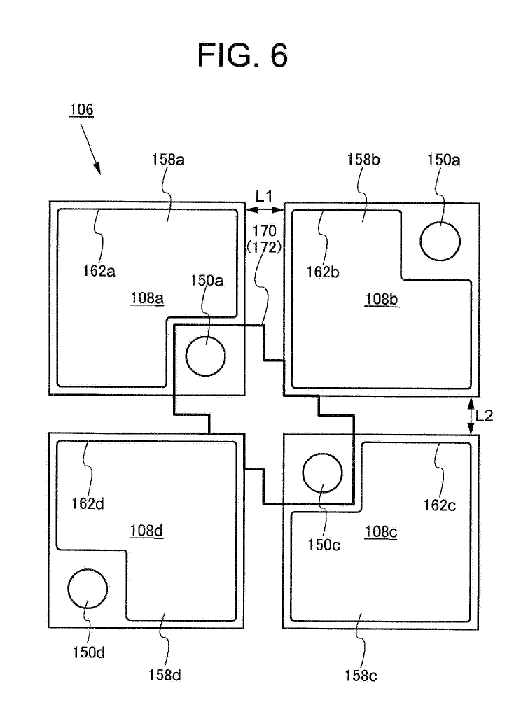

FIG. 6 is a plan view of the pixel electrode 106 in which a plurality of pixels 108 are arranged. Let it be assumed that each of the pixels 108 is configured as shown in FIG. 4. In FIG. 6, the pixels 108 (namely a first pixel 108a, a second pixel 108b, a third pixel 108c, and a fourth pixel 108d) include the pixel electrodes 158 (namely a first pixel electrode 158a, a second pixel electrode 158b, a third pixel electrode 158c, and a fourth pixel electrode 158d), respectively. The first pixel 108a, the second pixel 108b, the third pixel 108c, and the fourth pixel 108d are placed at predetermined intervals. A region between a pixel and an adjacent pixel is herein referred to as “inter-pixel region”.

The pixel electrodes 158 are electrically connected to the drive transistors, provided on a lower level than the pixel electrodes 158, via the contact holes 150 (namely a first contact hole 150a, a second contact hole 150b, a third contact hole 150c, and a fourth contact hole 150d), respectively. Outer edge portions of the pixel electrodes 158 and regions of the pixel electrodes 158 where the contact holes 150 are provided are covered with the fourth insulating layer 160. The contours of the openings 162 of the fourth insulating layer 160 are arranged over the pixel electrodes 158, and FIG. 6 uses solid lines to indicate lines showing the contours.

The third conductive layer 154 is provided on a lower level than the pixel electrodes 158 with the third insulating layer 156 interposed therebetween. FIG. 6 uses solid lines to indicate the shape of the open end of the opening 170 of the third insulating layer 156. The opening 170 has such a size as to encompass regions of the first and third contact holes 150a and 150c of the first and third pixels 108a and 108c and reach an adjacent pixel. That is, the open end of the opening 170 is provided so as to reach each of the first, second, third, and fourth pixel electrodes 158a, 158b, 158c, and 158d.

The open end of the opening 170 is provided so as to include at least two bend portions in an inter-pixel region. For example, one side of the open end of the opening 170 includes a first side extending in a direction normal to one side of each of the pixel electrodes 158 and a second side extending in such a direction as to cross the first side.

By causing the open end of the opening 170 provided in the third conductive layer 154 to include the bend portions, the length of one side in the inter-pixel region can be made longer than the direct distance between the adjacent pixels.

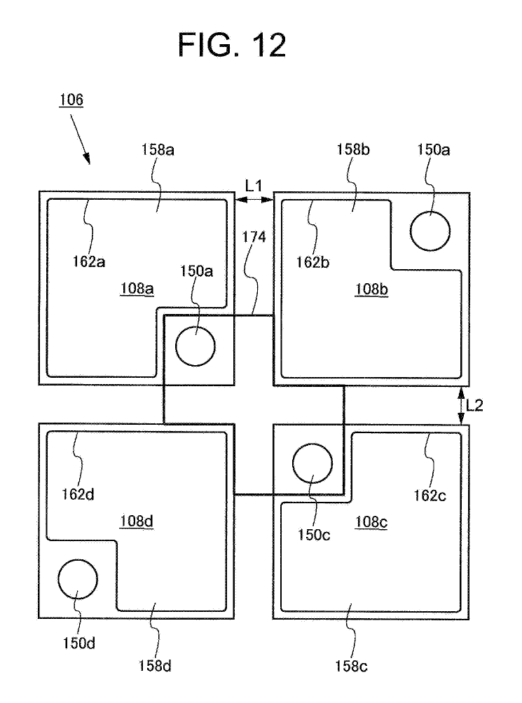

Meanwhile, FIG. 12 shows a case where an open end of an opening 174 provided in the third conductive layer 154 is linear. In this case, one side of the open end of the opening 174 overlaps part of each of the pixel electrodes 158 and reaches an adjacent pixel in a linear fashion. In such a case, once a step is formed in the third insulating layer 156 by the opening 174 and a conductive path is formed by an etching residue, the adjacent pixels are connected at the shortest distance, so that the pixels become likely to be short-circuited.

On the other hand, in the embodiment of the opening 170 shown in FIG. 6, the open end bends more than once. Even if the stepped portion 172 is formed in the third insulating layer 156 along the open end, the conductive path formed by the etching residue extending along the path becomes longer and can be made higher in resistance. This makes it possible to prevent the pixels from being short-circuited.

It should be noted that the bend portions of the open end of the opening 170 is not limited to those which bends at right angle but may be those which bend in curved lines. Further, one side of the open end may be partially or completely curved at least in the inter-pixel region.

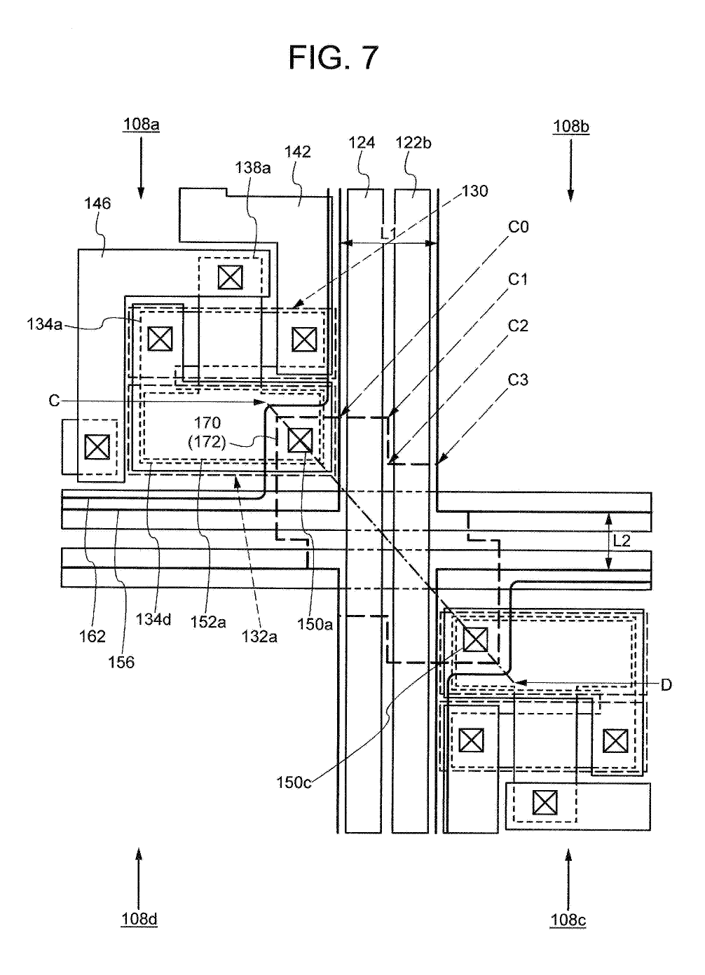

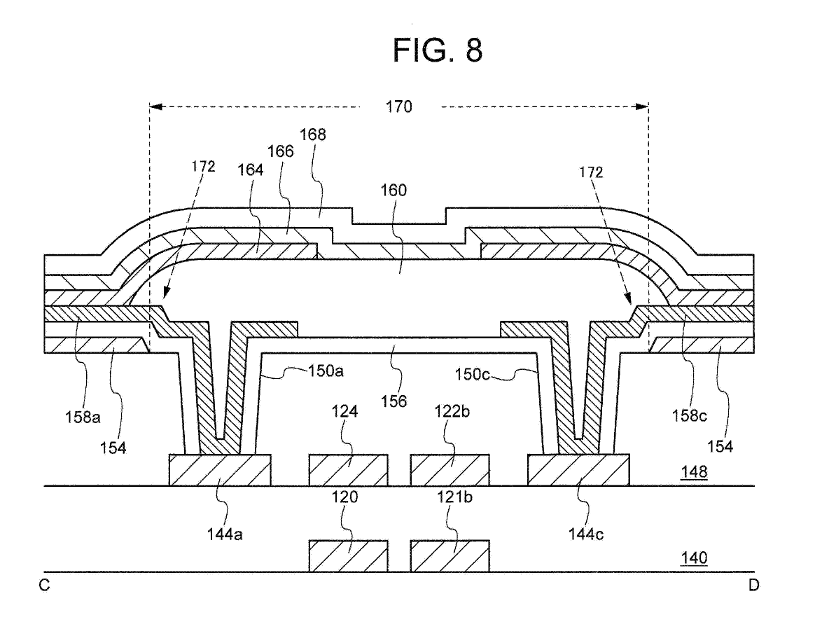

FIG. 7 and FIG. 8 are partially-enlarged views of the opening 170, shown in FIG. 6, of the third conductive layer 154 and the four pixels 108, shown in FIG. 6, which are adjacent to the opening 170. FIG. 7 is a plan view of the pixels, and FIG. 8 is a cross-sectional view taken along line C-D.

A first scanning signal line 120 and a second scanning signal line 121 are arranged in the inter-pixel region between the first pixel 108a and the fourth pixel 108d and in the inter-pixel region between the second pixel 108b and the third pixel 108c. A video signal line 122 and a power supply line 124 are arranged in the inter-pixel region between the first pixel 108a and the second pixel 108b and in the inter-pixel region between the third pixel 108c and the fourth pixel 108d. As shown in FIG. 8, these wires are arranged on a lower level than the pixel electrodes 158.

FIG. 7 shows an arrangement in which the first contact hole 150a of the first pixel 108a and the third contact hole 150c of the third pixel 108c face each other. FIG. 7 uses dotted lines to indicate the open end of the opening 170 of the third conductive layer 154 provided on a lower level than the pixel electrodes 158. A region of the opening 170 is covered with the fourth insulating layer 160 as shown in FIG. 8 and therefore serves as a non-luminous region in the pixel unit 106.

A portion of the opening 170 that corresponds to the first pixel electrode 108a partially overlaps the first pixel electrode 158a in a plan view, and other portions of the opening 170 spread to outer regions (inter-pixel regions between the first pixels 108a and its adjacent pixels) over the first pixel electrode 158a. The first contact hole 150a is arranged inside of the opening 170 in a plan view. A portion of the opening 170 that corresponds to the third pixel electrode 108c partially overlaps the third pixel electrode 158c in a plan view, and other portions of the opening 170 spread to outer regions (inter-pixel regions between the third pixels 108c and its adjacent pixels) over the third pixel electrode 158c. The third contact hole 150c is arranged inside of the opening 170 in a plan view.

As shown in FIG. 6 and FIG. 7, the open end of the opening 170 of the third conductive layer 154 reaches a region extending from the first pixel electrode 158a of the first pixel 108a to the second pixel electrode 158b of the second pixel 108b and reaches a region extending from the first pixel electrode 158a of the first pixel 108a to the fourth pixel electrode 158d of the fourth pixel 108d. The same applies to relationships between the second pixel 108b and the third pixel 108c and between the third pixel 108c and the fourth pixel 108d. A portion of the opening 170 provided in the first pixel 108a and a portion of the opening 170 provided in the third pixel 108c may spread to the inter-pixel region between the first pixel 108a and the third pixel 108c and be united to form a single opening. By thus providing the opening 170 of the second capacitive electrode 152b so that the opening 170 is connected to a plurality of pixels, the width of the opening 170 can be made larger. This allows leeway of alignment accuracy in the manufacturing process. This also allows a reduction in parasitic capacitance that is formed with a wire provided on a lower level.

In the configuration of the pixel unit according to the present embodiment, one side of the open end of the opening 170 provided in the third conductive layer 154 is longer than the direct distances L1 and L2 between the pixel electrodes of the adjacent pixels. The third insulating layer 156 over the third conductive layer 154 has the stepped portion 172 formed along the open end. This causes the conductive path extending along the stepped portion 172 to inevitably become longer even when a residue is produced along the stepped portion 172 by the step of pattering the pixel electrodes 158 provided on the upper surface of the third insulating layer 156. This makes it possible to make the conductive path formed by the residual substance higher in resistance and prevent the pixels from being short-circuited. This in turn makes it possible to prevent the occurrence of a luminous-point defect in the pixel unit 106 of the display device 100.

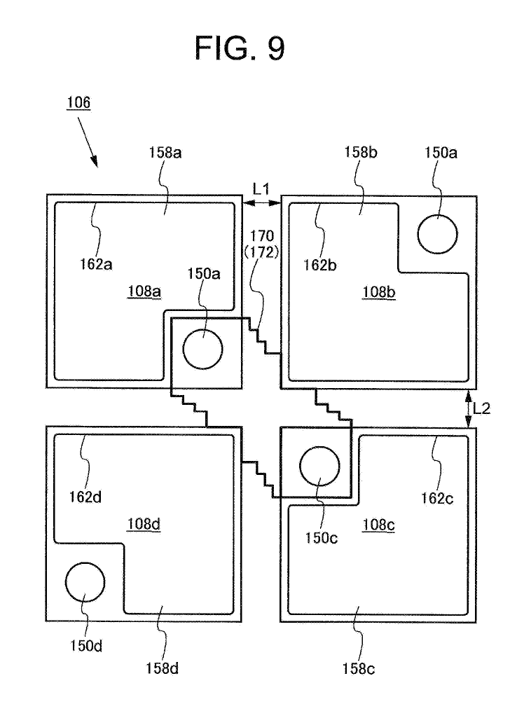

It should be noted that the shape of the opening 170 of the third conductive layer 154 is not limited to the embodiment shown in FIG. 6. The open end of the opening 170 may bend in a multistage manner as shown in FIG. 9. When the open end of the opening 170 is shaped in this manner, a conductive path formed by the etching residue of the conductor forming the pixel electrodes 158 bends in a complex manner even when the etching residue remains along the path. This makes it possible to prevent the conductive path from being continuous (break the conductive path) and make the conductive path higher in resistance.

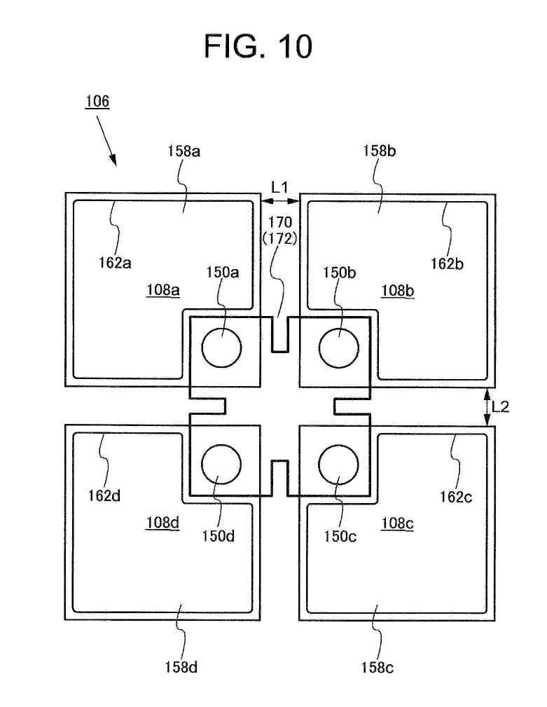

FIG. 10 shows an example in which the first contact hole 150a of the first pixel 108a, the second contact hole 150b of the second pixel 108b, the third contact hole 150c of the third pixel 108c, and the fourth contact hole 150d of the fourth pixel 108d are arranged so as to be adjacent to one another. In this case, one side that extends along the open end of the opening 170 bends at least twice, preferably four times, in an inter-pixel region. The opening 170 may be a single opening inside of which the contact holes 150 of the four pixels are present.

In the shape of the opening 170 shown in FIG. 10, too, one side that extends along the open end is longer than the interproximal direct distance between pixels. This makes it possible to prevent a short-circuit defect from being caused by the residue after the formation of the pixel electrodes.

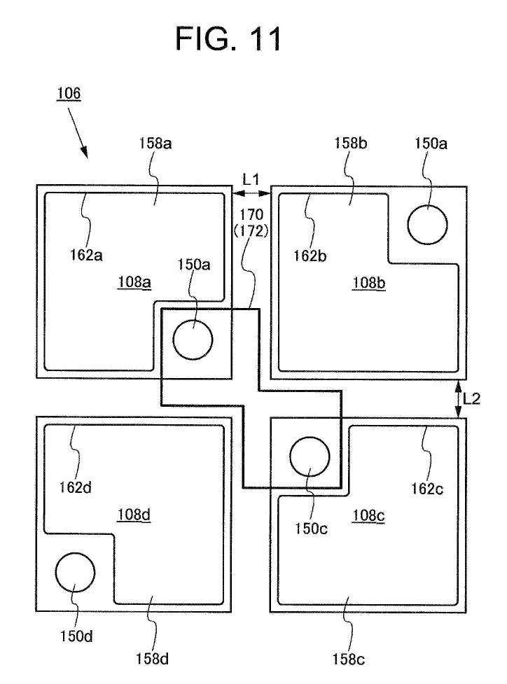

FIG. 11 shows an embodiment in which the open end of the opening 170 of the third conductive layer 154 does not reach an adjacent pixel. In such an embodiment of the opening 170, even when the open end does not reach an adjacent pixel and therefore a residue is produced in the stepped portion, the pixels can be prevented from being short-circuited. It should be noted that, in the opening 170 shown in FIG. 11, one side of the open end has a bend portion in an inter-pixel region.

As described above, according to the embodiment of the present invention, even when an insulating layer provided on a lower level than a pixel electrode includes a stepped portion and a conductive etching residue is produced in the stepped portion, a conductive path formed by the etching residue can be made higher in resistance. This makes it possible to prevent pixels from being short-circuited.

What is claimed is:

1. A display device comprising:
a conductive layer over an interlayer insulating layer;
a pixel electrode over the conductive layer; and
an insulating layer provided between the conductive layer and the pixel electrode,
wherein the pixel electrode is electrically connected to a transistor via a contact hole through the insulating layer and the interlayer insulating layer,
the conductive layer has an opening having the contact hole inside and spreading to an outer region outside of the pixel electrode,
the opening has an open end, and
one side of the opening bends in the outer region outside of the pixel electrode.

2. The display device according to claim 1, wherein the one side includes at least two bend portions in the outer region outside of the pixel electrode.

3. The display device according to claim 1, wherein the one side includes a first side extending in a direction normal to one side of the pixel electrode and a second side extending in such a direction as to cross the first side.

4. The display device according to claim 1, wherein the insulating layer includes a stepped portion in a surface of the insulation layer, the stepped portion overlaps the open end of the opening.

5. The display device according to claim 4, wherein at least part of the pixel electrode overlaps the stepped portion.

6. The display device according to claim 1, further comprising a capacitive element formed in an overlap region of the conductive layer, the insulating layer, and the pixel electrode.

7. The display device according to claim 1, further comprising an organic layer and a counter electrode over the pixel electrode.

8. A display device comprising:
a conductive layer over an interlayer insulating layer;
a plurality of pixel electrodes arranged over the conductive layer; and
an insulating layer provided between the conductive layer and the plurality of pixel electrodes,
wherein each of the pixel electrodes is electrically connected to a transistor via a contact hole through the insulating layer and the interlayer insulating layer,
each of the pixel electrodes, the conductive layer has a plurality of openings having the contact holes inside and spreading to outer regions outside of the pixel electrodes, respectively,
each of the openings has an open end, and
one side of the each of the openings bends in the outer regions outside of the pixel electrodes.

9. The display device according to claim 8, wherein the one side includes at least two bend portions in each of the outer regions outside of the plurality of pixel electrodes.

10. The display device according to claim 8, wherein the one side includes a first side extending in a direction normal to one side of a corresponding one of the pixel electrodes and a second side extending in such a direction as to cross the first side.

11. The display device according to claim 8, wherein the plurality of openings are continuous with openings of adjacent ones of the plurality of pixel electrodes.

12. The display device according to claim 11, wherein the plurality of openings includes a plurality of the contact holes in openings provided in the plurality of pixel electrodes so as to be continuous with the adjacent pixel electrodes.

13. The display device according to claim 8, wherein in an interproximal region where the plurality of pixel electrodes are placed at a space therebetween, the length of one side of the open end of each of the openings is longer than an interproximal distance between the pixel electrodes.

14. The display device according to claim 10, wherein the one side has the first side and the second side arranged in an interproximal region where the plurality of pixel electrodes are placed at a space therebetween.

15. The display device according to claim 8, wherein the insulating layer includes a stepped portion in a surface of the insulation layer, the stepped portion overlaps the open end of the opening.

16. The display device according to claim 15, wherein at least part of each of the pixel electrodes overlaps the stepped portion.

17. The display device according to claim 8, further comprising a plurality of capacitive elements formed in an overlap region of the conductive layer, the insulating layer, and the plurality of pixel electrodes.

18. The display device according to claim 8, further comprising an organic layer and a counter electrode over the pixel electrodes.
